(19) United States
(12) Patent Application Publication
(10) Pub. No.: US 2010/0078635 A1
(43) Pub. Date: Apr. 1, 2010

(54) SEMICONDUCTOR DEVICE

(75) Inventors: Yuki Kuroda, Tachikawa (JP); Makoto Saen, Kodaira (JP); Hiroyuki Mizuno, Musashino (JP); Kiyoto Ito, Kokubunji (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/465,819

(22) Filed: May 14, 2009

(30) Foreign Application Priority Data
Sep. 29, 2008 (JP) 2008-249495

(51) Int. Cl. H01L 23/58; H01L 21/50

(52) U.S. Cl. 257/48; 438/107; 257/E25.029; 257/E21.499

(57) ABSTRACT

As the transfer between a processor LSI and a memory has been increasing year by year, there is a demand for increasing the traffic amount and reducing the power required for communication. With this being the condition, a method of stacking LSIs thereby reducing the communication distance is being contemplated. However, the inventors have found that the reduction of cost in the stacking process and the increase in the degree of freedom of selecting the memory LSI to be stacked are required for a simple stacking of processor LSIs and memory LSIs as so far practiced. An external communication LSI including a circuit for performing the communication with the outside of the stacked LSI at a high rate of more than 1 GHz; a processor LSI including a general purpose CPU etc.; and a memory LSI including a DRAM etc. are stacked in this order and those LSIs are connected with one another with a through silicon via to enable a high speed and high volume communication at a shortest path. Further, an interposer for facilitating the connection with the processor LSI is connected to the input terminal of the memory LSI to be stacked thereby increasing the degree of freedom in selecting memories.

### CLAIM OF PRIORITY

The present application claims priority from Japanese patent application JP 2008-249495 filed on Sep. 29, 2008, the content of which is hereby incorporated by reference into this application.

### BACKGROUND OF THE INVENTION

1. Field of the Invention

The present invention relates to a group of LSIs which are implemented in a stacked form.

2. Background Art

As the microfabrication technology advances, the performance of LSIs has been improved by integrating more transistors in a single chip. However, due to the effects such as the limits of miniaturization and the increases in the cost of utilizing state-of-the-art processing, further promotion of the integration into a single chip as so far practiced will not necessarily be a best solution. Accordingly, a three-dimensional integration through stacking of a plurality of LSIs will be a promising technology. With this being the case, communication function between LSIs to be stacked and between the LSI to be stacked and the outside thereof will become critical. As the communication scheme for such stacked LSIs, wired schemes (a method of making an electrode (hole) in silicon of LSI substrate) and wireless schemes are being studied.

In high performance media processing and network processing in recent years, the traffic volume between a processor LSI including a CPU and a memory has been increasing year by year, and the communication capability of this section has become a principal factor to determine the overall performance. JP Patent Publication (Kokai) No. 2004-327474 refers to the configuration in which an LSI for performing the communication between a memory and components on the board, and a plurality of memory LSIs are stacked. By stacking a plurality of memories, each of which is mounted on the upper plate of the system board, the wiring length to the memory can be decreased thereby contributing to the increase of speed and reduction of power consumption.

### SUMMARY OF THE INVENTION

With the above described background art in mind, the present inventors contemplates that in order to achieve further improvement in performance, reduction of power consumption, and increase in space efficiency, it will be effective to stack LSIs such as a processor in conjunction with memory LSIs.

Under such circumstances, the present inventors have found a problem with the stacking order when stacking the above described processor LSIs and memory LSIs. In general, memories have significantly different circuit configurations and design processes etc. depending on their types such as DRAM, SRAM, and the like. Moreover, it may also be assumed that the type of memory to be applied is changed in the design stage. In order to cope with such situations, it becomes necessary that the part of the system other than the memory LSI has the versatility to allow changes in specifications such as the type and the configuration, etc. of the memory.

Further, when designing a semiconductor device, there may be a case in which the vendor which designs the external communication LSI for performing external communication and the processor LSI is different from the vendor which designs the memory. In such a case, it must be made possible that a memory LSI designed by a different vendor may be used to form a stack.

Further, when the memory LSI is stacked in a separate process, it is desirable that the communication between the external communication LSI and the processor LSI can be tested prior to the stacking of the memory LSI so that when there is a defect between the external communication LSI and the processor LSI, it can be detected before the stacking of the memory LSI.

However, means for solving such problems cannot be found in the above described JP Patent Publication (Kokai) No. 2004-327474.

An overview of typical aspects of the present invention disclosed herein to solve the above described problem will be briefly described as follows.

That is a semiconductor device, comprising a package board; a first LSI connected to the package board and including a communication circuit for performing communication via the package board; a second LSI provided above the first LSI and for performing arithmetic processing; a third LSI provided above the second LSI and including a first storage device for storing a result of arithmetic processing of the second LSI, the first storage device including a plurality of first memory cells provided at intersection points of a plurality of first bit lines and a plurality of first word lines; and a first through silicon via provided so as to pass through the second LSI and for electrically connecting the first, second, and third LSIs with one another.

Alternatively, that is a semiconductor device comprising: a package board; a first LSI connected to the package board and including a communication circuit for performing communication via the package board; a second LSI provided above the first LSI and for performing arithmetic processing using data from the communication circuit; a first through silicon via configured to pass through the second LSI and for electrically connecting the first and second LSIs; and an interposer layer provided above the second LSI, electrically connected to the first through silicon via, and provided on its top with a connection terminal for connecting another circuit.

Further, that is a method of manufacturing a semiconductor device in which a plurality of LSIs are stacked, the method comprising: a first step of stacking a first LSI above a package board, the first LSI including a communication circuit for performing communication via the package board; after the first step, a second step of stacking a second LSI above the first LSI, the second LSI being adapted to perform arithmetic processing using data from the communication circuit; after the second step, a third step of providing an interposer layer above the second LSI, the interposer layer being adapted to connect between the first LSI or the second LSI and an LSI other than the first LSI and other than the second LSI with wiring; and after the third step, a fourth step of providing a first through silicon via configured to pass through the second LSI and adapted to electrically connect the first LSI and the second LSI with each other.

The present invention will realize a reduction of cost in the stacking process of a memory LSI, processor LSI, and external communication LSI and an increase of the degree of flexibility for arranging the memory LSI to be stacked.

### BRIEF DESCRIPTION OF THE DRAWINGS

FIG. 1 is a block diagram of an LSI package to be stacked.

FIG. 2 is a block diagram of a memory LSI to be stacked.

FIG. 3 is a block diagram of a processor LSI to be stacked.

FIG. 4 is a block diagram of an external communication LSI to be stacked.

FIG. 5 shows the positional relationship between LSIs in a stacked LSI package.

FIG. 6 shows the control section for through silicon vias in a processor LSI.

FIG. 7 shows the circuit in the control section for through silicon vias.

FIG. 8 shows the control section for through silicon vias in a memory LSI.

FIG. 9 shows the control section for through silicon vias in an external communication LSI.

FIG. 10 shows another configuration of an LSI package to be stacked.

FIG. 11 is a block diagram of an interposer for connecting a memory LSI to be stacked.

FIG. 12 shows a test circuit for an LSI to be stacked.

### DESCRIPTION OF SYMBOLS

100: Package board
101: System board
110 to 111: Memory LSI
120 to 121: Processor LSI
130: External communication LSI
140 to 141, 145 to 146, 150 to 151, 160 to 161, 190 to 191: Through silicon via
170 to 171, 175 to 176, 180 to 181, 185 to 186: Bonding wire
200 to 203: Storage section
220 to 223: Through silicon vias
210 to 213: Communication control block
250, 260 to 267: Electrode
300 to 307: Processing unit
350 to 351: DMAC
355 to 356: Peripheral circuit block
360 to 361: Test block
365 to 366: Control block
370 to 373: Communication control block
380 to 383: Through silicon vias
385 to 388: Control block
390 to 391: On-chip interconnect
395: Bridge circuit
340: Electrode
310 to 317: Electrode
400 to 401: Interface circuit block
410 to 411: Control block
420 to 421: Microcontroller
430 to 431: Test block
460 to 463: Communication control block
450 to 451: On-chip interconnect
440 to 441: DMAC
600: Designating signal
610: Control block
620 to 622: Use request signal for through silicon vias 220 to 223
630 to 632: Use permission signal for through silicon vias 220 to 223
640 to 641: Through silicon via
650 to 651: Through silicon via
660: Interface circuit
670: Data conversion circuit
680 to 682: Signal control block
690 to 691: Control signal
800: Interface circuit
801: Data conversion circuit
820: Signal control block
810: Signal control block
830: Control signal
900: Interface circuit
901: Data conversion circuit
960: Control block
902: Data conversion circuit
1000: Memory LSI
1010: Interposer
1140: DRAM controller
1120 and 1130: Through silicon via
1100: Wiring resistor
1110: Power supply
1200: Control section
1210: Write section
1230: Storage section
1220: Read-out section
1250: ROM
1240: Register

### DETAILED DESCRIPTION OF THE PREFERRED EMBODIMENTS

### Example 1

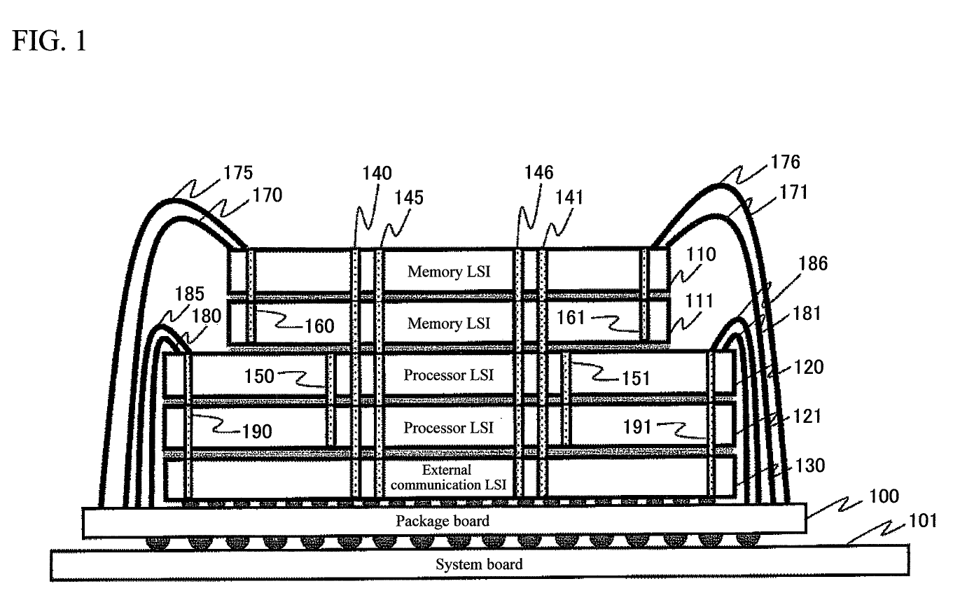

FIG. 1 shows an embodiment of a stacked LSI, in which the stack section of the stacked LSI is shown. In the present embodiment, an external communication LSI 130 is stacked on top of the package board 100; processor LSIs 120 and 121 mounted with a computing unit are further stacked on top of the foregoing; and memory LSIs 110 to 111 for storing data are stacked further on top of the foregoing. The external communication LSI includes a circuit for performing a high speed wired communication at a communication frequency of higher than 1 GHz with components on the system board outside the stacked LSI so that a high speed communication with the outside of the stacked LSI is performed via the external communication LSI.

The external communication LSI is flip connected with its circuitry/wiring surface facing toward the package board side. The processor LSI corresponds to multipurpose processors such as a CPU, dedicated processors such as a graphic accelerator, dynamically reconfigurable processors in which a large number of arithmetic circuits such as an adder and multiplier are arranged and connected with each other by a switch circuit, and LSIs mounted with an FPGA. The memory LSI corresponds to LSIs mounted with storage devices made up of memory cell arrays such as a DRAM, SRAM, flash memory, magnetic memory, and others.

In this way, the invention according to FIG. 1 is characterized in that an external communication LSI, a processor LSI, and a memory LSI are stacked in this order in a semiconductor package, and these LSIs are connected by through silicon vias to perform a high speed and large volume communication. In this configuration, a through silicon via is an electrode fabricated by opening a hole through the substrate silicon and filling the hole with a conductive material, which enables to electrically connect between stacked LSIs.

The reason why the order of the stacking is decided as described above is as follows.

First, there is a case in which the manufacturing process of the memory LSI is different from those of the external communication LSI and the processor LSI, as the result of which, in-house manufacturing thereof may be difficult. For example, in the design process of a DRAM, since the DRAM has a structure including a capacitor, it is different from a general LSI manufacturing process. Therefore, considering the case in which the external communication LSI and the processor LSI are developed in-house and the DRAM LSI is purchased from another company, disposing the memory LSI at the uppermost position will make the assembly and testing easier and improve the yield of the package.

Further, when the memory LSI is provided in advance with a large number of input/output terminals for stacking, disposing it at the uppermost position will obviate the need of subjecting the memory LSI to a process of forming electrodes on one side or from the upper side to the lower side, and thereby enable to improve the yield of the stacked package and reduce the development cost.

Next, for the external communication LSI, it is required to form a transmission path with less branches and seams in order to perform a high speed communication. Thus, disposing the external communication LSI in the lowermost layer will enable to connect it directly to the package board, and thereby facilitate the forming of a transmission path with less branches and seams enabling to perform a high speed communication more efficiently.

Further, as described above, the external communication LSI and the processor LSI may be manufactured by a general design process. Subjecting the external communication LSI and the processor LSI to an operation test at the time of their manufacturing and stacking in-house before the stacking of the memory LSI will make it possible to reduce the loss at the time of stacking failure.

From the above described reason, the memory LSI is disposed in the uppermost layer, the external communication LSI in the lowermost layer, and the processor LSI in between. Thereafter, through silicon vias 140 to 141 are provided so that the communication between each LSI layer is enabled. In FIG. 1, although the through silicon vias 140 to 141 are configured to pass through all the LSIs, there is no need of passing through all the LSIs. Arranging the external communication LSI such that its surface on which circuitry is disposed faces upward (face-up) will obviate the need of the through silicon vias 140 to 141 passing through the external communication LSI. Further, arranging the memory LSI such that its surface on which circuitry is disposed faces downward (face-down) will obviate the need of the through silicon vias 140 to 141 passing through the memory LSI. Alternatively, using the below described interposer will also obviate the need of the through silicon vias 140 to 141 passing through the memory LSI. Thus, as a minimum configuration, by configuring that the through silicon vias 140 to 141 pass through only the processor LSI, it is made possible to realize a configuration to enable the communication throughout the SoC.

In addition, when the memory LSI is a particular type of memory, disposing the memory LSI in the uppermost position will be effective in improving the heat dissipation of the memory LSI. For example, when the memory LSI is a DRAM, a problem may arise in that the data refresh time of the DRAM may be decreased due to its heat. Alternatively, when the memory LSI is a phase-change memory, another problem may arise in that the storage information is disturbed by heat since the phase-change element performs the writing of the storage information by heat.

Thus, when stacking a memory of which operational performance will be significantly affected by heat, stacking the memory LSI at the uppermost position and providing a radiator plate on the top face will enable to improve heat dissipating effect. This will, in the case of a memory such as the above described phase-change memory, decrease the disturbance to the storage information resulting in an improvement of reliability. Also, in the case of a DRAM, the improvement of heat dissipation property will have an especially profound effect. That is, in the case of a DRAM, it becomes possible to decrease the refresh frequency, which will lead to a profound effect in achieving an improvement in communication and power performances.

In FIG. 1, stacked LSIs are connected by through silicon vias (140 to 141, 145 to 146, 150 to 151, 160 to 161, 190 to 191) in which wiring is formed by opening a hole through the silicon substrate in the vertical direction and filling that hole with conductive material, and bonding wires (170 to 171, 175 to 176, 180 to 181, 185 to 186). The through silicon vias 145 to 146 and the through silicon vias 190 to 191 are through silicon vias for providing power supply. The through silicon vias 145 to 146 is the through silicon via for providing a common power supply to the memory LSI, the processor LSI, and the external communication LSI, and the power supply is connected to the power supply lines of the memory LSI and the processor LSI from outside the package via the package board, the external communication LSI, and the through silicon vias 145 to 146. The through silicon vias 190 to 191 are a through silicon via for providing a power supply which is required only by the processor LSI, and the power supply is connected to the power supply line of the processor LSI and the through silicon vias 190 to 191 from outside the package via the package board, and the bonding wires 180 to 181. This power supply may be provided to the external communication LSI by the through silicon vias 190 to 191. Similarly, the through silicon vias 160 to 161 are a through silicon via for proving a power supply which is required only by the memory LSI, and the power supply is connected to the power supply line of the memory LSI and the through silicon vias 160 to 161 from outside the package via the package board and the bonding wires 170 to 171. That is, using the wire bonding and the through silicon via in combination allows the power supplies for the processor LSI and the memory LSI to be provided either from the upside and downside thereof so that it becomes possible to provide a stable power supply to a processor LSI and a memory LSI which are provided at upward positions. This effect becomes more profound when a larger number of LSIs are stacked.

Now, the reason why the memory LSI and the processor LSI have the through silicon vias 160 to 161 and the through silicon vias 190 to 191 besides the through silicon vias 145 to 146 is to provide a power supply with a different voltage to respective LSIs. The paths through which different voltages are supplied are more stabilized when they are made up of different terminals. For example, there may be a case in which the power supply voltage provided to the processor LSI will be the lowest, the power supply voltage provided to the memory LSI is higher then that provided to the processor LSI, and the power supply voltage provided to the external communication LSI is even larger. In such a case, providing power supply to each LSI by preparing separate paths will make it possible to avoid unnecessary load to be imposed on other circuits such as the through silicon vias 145 to 146, thereby preventing the malfunctions of the circuits.

Next, the communication paths to and from each LSI and the outside of package in the present embodiment will be described. The communication between processor LSIs is by the through silicon vias 150 to 151. The communication between the processor LSI and the memory LSI is by the through silicon vias 140 to 141. The communication between the processor LSI and the external communication LSI is by the through silicon vias 140 to 141, the bonding wires 185 to 186, and the wiring in the package board 100. The communication between the processor LSI and the outside of package is by the through silicon vias 140 to 141, the bonding wires 185 to 186, the wiring in the package board 100, and the wiring in the system board 101. The communication between the external communication LSI and the memory LSI is by the through silicon vias 140 to 141 and the bonding wires 175 to 176. The communication between the external communication LSI 130 and the outside of package is via the wiring in the package board 100 and the wiring in the system board 101. The communication between the memory LSI and the outside of package is by the through silicon vias 140 to 141, the external communication LSI 130, the wiring in the package board 100, and the wiring in the system board 101. It is noted that communication used herein refers not to communication in a narrow sense but to the input/output of all kinds of information including reset signals, endian signals, initial value signals such as operational frequencies and terminal settings, identification signals for LSIs and others, but excepting power supplies.

As the path for communication, there are provided through silicon vias 140 to 141 which pass through each of the processor LSI, the memory LSI, and the external communication LSI, and through silicon vias 150 to 151 which connect between the processor LSIs. Further, the memory LSI and the package board are connected by the bonding wires 175 to 176 for data communication. Similarly, the processor LSI and the package board are connected by the bonding wires 185 to 186.

A typical operation of this system is as follows: the external communication LSI 130 reads data to be processed such as images and communication packets from the outside of package into the stacked memory LSIs 110 to 111, and the processor LSIs 120 to 121 perform certain arithmetic processing on that data. Then, the result is stored in the memory LSIs 110 to 111, and the external communication LSI 130 outputs the result from the memory LSIs 110 to 111 to external storages and networks. Since the stacked LSI of the present invention is configured such that the external communication LSI, the processor LSI, and the memory LSI are stacked in that order, it is made possible to improve the heat dissipating performance of the memory LSI by such as attaching a radiator plate on the top face of the stacked package, and when the stacked LSI is used in the applications in which the time for retaining data in the memory LSI in the stacked package is long, it becomes possible to realize the reduction of the energy consumption of the entire stacked LSI.

In FIG. 1, as the through silicon via, there are provided, besides the through silicon vias 140 to 141 for connecting the entire system, the through silicon vias 150 to 151. However, the communication between the processor LSIs, which is performed by using the through silicon vias 150 to 151, can also be performed by using common through silicon vias 140 to 141. In this case, it is possible to reduce the number of the through silicon vias of the processor LSI, which is advantageous in view of the area of the processor LSI.

On the other hand, providing the through silicon vias 150 to 151 for connecting only between the processor LSIs will enable to realize a high speed communication which is required for between the processor LSIs.

In the present example, although the through silicon vias 150 to 151 for connecting part of stacked LSIs are described such as to connect only between the processor LSIs, they may be a through silicon via for connecting between certain LSIs. For example, as the through silicon via for connecting part of stacked LSIs, other schemes for connecting LSIs (for example, a processor LSI and a memory LSI) may be adopted. In this case, whichever LSIs are passed through, a high speed communication is enabled between the connected LSIs.

Further, although in the embodiment of FIG. 1, the stacked LSIs are directly connected, there may be a case in which an interposer layer including a wiring for adjusting the terminal position is interposed between the memory LSI and the processor LSI, and between the processor LSI and the external communication LSI. The interposer enables to facilitate the alignment between the position of the through silicon via of the memory LSI and the position of the through silicon via of the processor LSI when they do not coincide. Also, a regenerated wiring layer may be used for the same purpose.

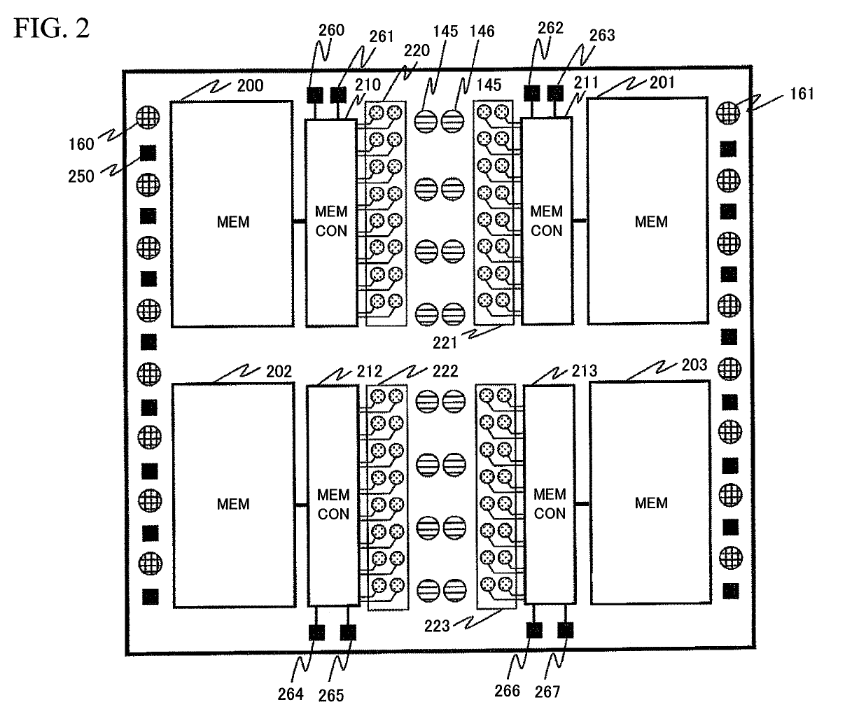

FIG. 2 shows an embodiment of the memory LSI. The storage section 200 to 203 is a block including a memory array, and through silicon vias 220 to 223 is through silicon vias for communicating with the processor LSI and the external communication LSI and corresponding to the through silicon via 140 to 141 of FIG. 1. The communication control block 210 to 213 is a block for performing communication using the through silicon vias 220 to 223, and the through silicon vias 220 to 223 and the communication control block 210 to 213 are combined to constitute an input/output port from and to other LSIs. The electrode 250 is an electrode for providing power supply through a bonding wire (170 to 171 of FIG. 1), and the power supply connected to the electrode 250 is provided as the power supply of the memory LSI, further connected to the through silicon via 160 to 161 so that power supply is also provided to the memory LSI in the lower layer. The electrode 260 to 267 is connected with the bonding wire 175 to 176 of FIG. 1 and is used for endian signals, identifier signals of LSI, signals for specifying the functions of LSI, and others.

The memory LSI 110 to 111 receives a read/write request of data output by the processor LSI 120 to 121 and the external communication LSI 130 by the through silicon vias 220 to 223 and, according to the request, performs the read/write processing from and to the storage section 200 to 203, to output, in the case of read processing, reply information including read data to the through silicon vias 220 to 223. The read/write request includes information to perform the synchronization between the LSIs, LSI selection information for selecting one from a plurality of stacked memory LSIs, command information indicating read/write, address information, processing identifiers, and write data in the case of writing. The reply information includes information to perform the synchronization between the LSIs, read data, and processing identifiers. The processing identifier is information to be included in a read/write request to a memory LSI, and the memory LSI causes the processing identifier to be included in the reply information. The processor LSI 120 to 121 and the external communication LSI 130, which are the originator of a read/write request, select replay information corresponding to the request issued by themselves by observing the processing identifier. When a large number of stacked LSIs make a request to the memory LSI 110 to 111, the processing identifier becomes necessary since requests from other LSIs are also output to the through silicon via. In this respect, the processing identifier refers to data on the source and the destination when a read/write request is made. Adding this processing identifier allows to distinguish LSIs even when the same kinds of LSIs are stacked, and therefore makes it possible to stack the same kind of LSIs thereby improving the scalability. Further, the request signal is added with a signal of the below described arbitration request.

Thus, making a request added with a processing identifier will allow a plurality of LSIs to share a certain common through silicon via.

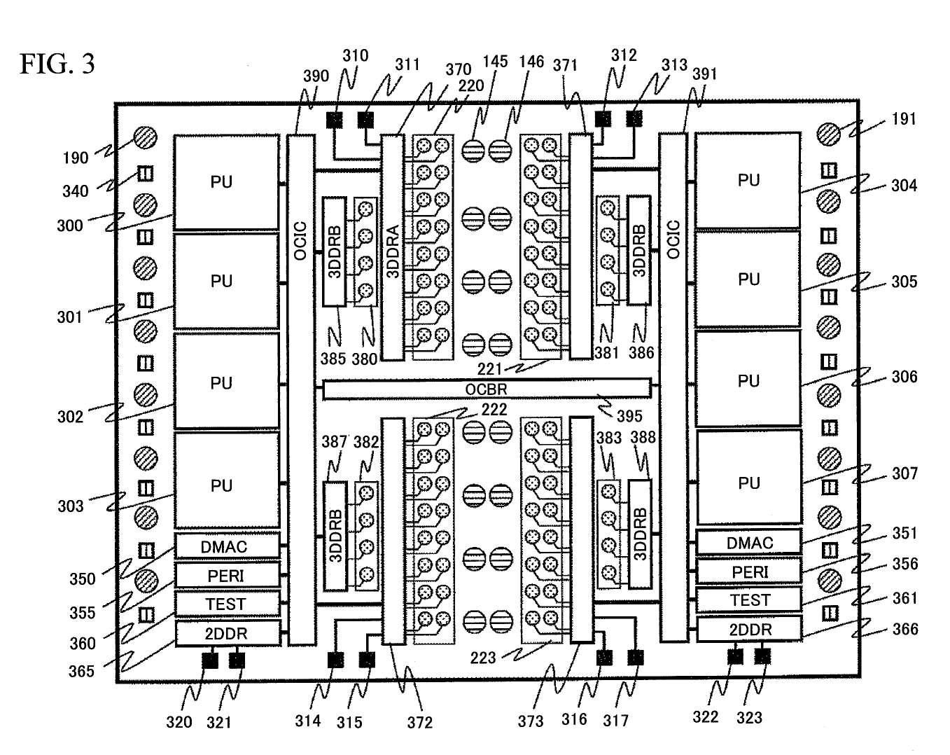

FIG. 3 shows an embodiment of a processor LSI. The processing unit 300 to 307 is a block for performing arithmetic processing; the DMAC 350 to 351 is a data transfer block; the peripheral circuit block 355 to 356 is a block including an interrupt control, clock control, and timer; the through silicon vias 220 to 223 are through silicon vias for performing the communication with the memory LSI and the external communication LSI; communication control block 370 to 373 is a block for controlling the communication to be performed by the LSI by using through silicon vias 220 to 223, and the through silicon vias 220 to 223 and the communication control block 370 to 371 are combined to constitute an input/output from and to with other LSIs. The through silicon vias 380 to 383 are through silicon vias for performing the communication with other processor LSIs, the control block 385 to 388 is a block for performing communications by using the through silicon vias 380 to 383. The test blocks 360 to 361 are a block for performing an operational test of the processor LSI and the external communication LSI; the control block 365 to 366 are a control block for performing the communication to the external communication LSI and a low speed communication to outside the stacked LSIs via a bonding wire; the on-chip interconnect 390 to 391 is a block for connecting between on-chip blocks; the bridge circuit 395 is a bridge circuit for connecting between the on-chip interconnects 390 to 391; the through silicon via 145 to 146 and the through silicon vias 190 to 191 are the through silicon via for providing power supply shown in FIG. 1; the electrode 340 is an electrode for providing power supply through a bonding wire (180 to 181 of FIG. 1); and the power supply provided through the electrode 340 is further connected to the through silicon via 190 to 191 as the power supply of the supplied processor LSI to provide power supply to the processor LSI in lower layer. The electrode 310 to 317 is connected with bonding wire 185 to 186 of FIG. 1 and is used such as to specify endian signals, identifier signals of LSI, and signals for specifying the function of LSI.

When a read/write of data from and to the storage region in the memory LSI takes place from the processing unit 300 to 307, DMAC 350 to 351, and others, the request is transferred to the communication control block 370 to 373 via the on-chip interconnect 390 to 391, and the communication control block 370 to 371 outputs, based on the request, a data read/write request to the memory LSI 110 to 111 by the through silicon vias 220 to 223. The communication control block 370 to 371 receives reply data to the access from the memory LSI 110 to 111 by through silicon vias 220 to 223, and the communication control block 370 to 371 outputs the information to the processing unit 300 to 307 and DMAC 350 to 351, which have made a request to the memory LSI 110 to 111, via the on-chip interconnects 390 to 391. The through silicon vias 380 to 383 indicate the through silicon via 150 to 151 shown in FIG. 1 and are used for the communication between the processor LSIs. The through silicon vias 380 to 383 includes: read/write request signals from a processing unit 300 to 307 or DMAC 350 to 351 in a certain processor LSI to the other processor LSI; signals for replying the read/write request; signals relating to an interrupt between processor LSIs; signals for keeping memory coherence between the processor LSIs; signals for timing synchronization between the processor LSIs; signals for supporting the software debugging of the processor LSI. In this configuration, disposing interfaces at the same place between LSIs will enable to perform the communication only in the vertical direction when they are stacked. Then, compared with case in which communication is performed in horizontal direction or a slanting direction, the communication within the surface in each LSI becomes unnecessary thereby reducing the area cost.

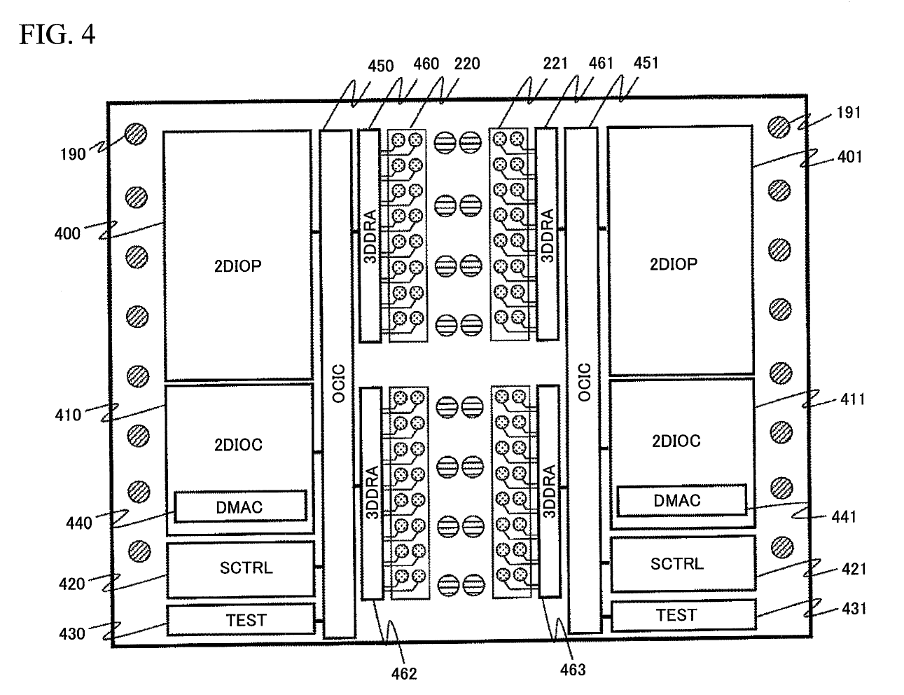

FIG. 4 shows an embodiment of the external communication LSI 130. The interface circuit block 400 to 401 is a block for performing a high speed communication with components outside the 3D stacked package; and the control block 410 to 411 is a block for controlling the interface circuit block 400 to 401; the microcontroller 420 to 421 is a small microcontroller for controlling the control block 410 to 411, the test block 430 to 431 is a block for performing an operational test of the processor LSI and the external communication LSI; the through silicon vias 220 to 223 are through silicon vias for communicating with the memory LSI; the communication control block 460 to 463 is a block for performing communications by using the through silicon vias 220 to 223; and the on-chip interconnect 450 to 451 is a block for connecting between the on-chip blocks. The control block 410 to 411 includes DMAC 440 to 441 for performing data transfer between address regions specified in a built-in register. Further, the microcontroller 420 to 421 executes the processing relating to the communication with the other stacked LSIs and the outside of package, such as a program for performing the communication with the processor LSI and a program for setting the register of the control block 410 to 411.

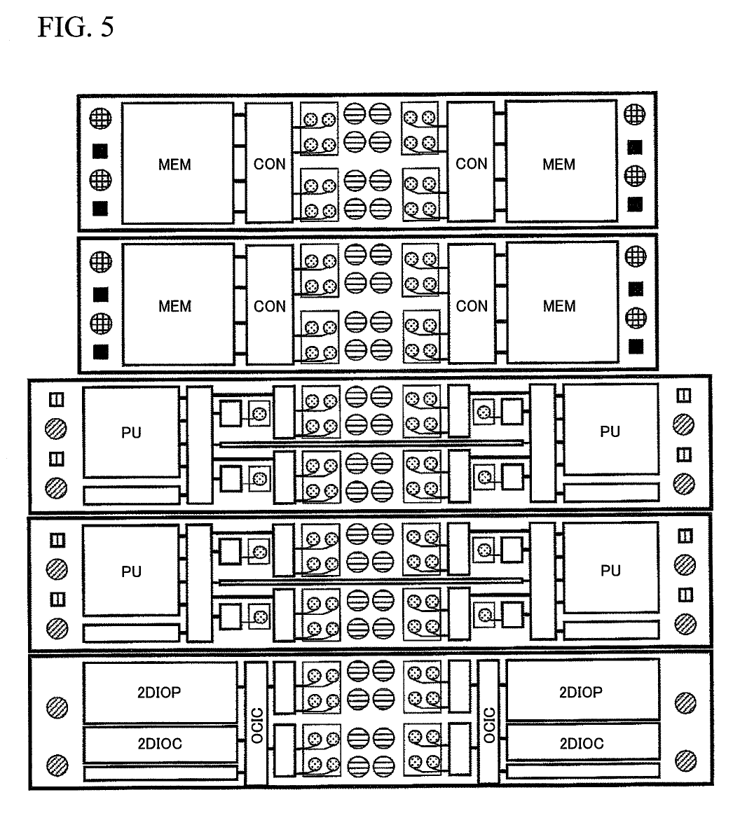

FIG. 5 shows the positional relationship among stacked LSIs. As shown in the figure, an external communication LSI, processor LSIs, and memory LSIs are stacked from the bottom; and sharing of a power supply and transfer of signals are performed by through silicon vias located in the middle portion of each LSI in the figure. Each memory LSI has four input/output ports, to each of which through silicon vias 220 to 223 are connected. The processor LSI and the external communication LSI are connected to the through silicon via, and the processor LSI and the external communication LSI use the shared through silicon vias 220 to 223 in a time-division manner to access the memory LSI. Since the respective through silicon vias 220 to 223 are shared by a plurality of LSIs, the LSIs cannot access the memory at the same time. For that reason, respective through silicon vias 220 to 223 are provided with an arbitration function, which arbitrates the use request for respective through silicon vias 220 to 223 from the processor LSI 120 to 122 and the external communication LSI 130, and gives the right of using the through silicon vias 220 to 223 to either one of the processor LSI 120 to 121 and the external communication LSI 130. This arbitration function may be arranged such that the LSI in which an arbitration function block to be executed for each through silicon via exists is varied; for example, the arbitration function of a certain through silicon via is included in a communication control block of the processor LSI 120, and the arbitration function of a different through silicon via is included in a communication block of the external communication LSI. In this respect, a method of making a particular LSI include an arbitration function will be described later.

When there is a processor LSI or an external communication LSI with which communication is desired through a certain through silicon via, a use request is issued to the LSI which includes the block for arbitrating the target through silicon via, and the LSI which is given a permission of use performs access to the memory LSI or other LSIs using the through silicon via.

The reason why the connection between the memory LSI and the processor LSI, and between the processor LSI and the external communication LSI are performed as described above is that even when the number of stacking layers changes, the same type of connection scheme can be employed to cope with that situation, thus exhibiting a high scalability to the number of stacked layers.

On the other hand, the through silicon vias 380 to 383 are electrodes for performing the communication between processor LSIs. This through silicon via is used for accessing an on-chip memory and a functional circuit in another processor LSI. For example, when a processing unit 300 in the processor LSI 120 intends to perform read/write from and to a memory region in the processing unit 301 of the processor LSI 121, the processing unit 300 in the processor LSI 120 generates a read/write request to the on-chip interconnect 390 to be connected with. This request includes: requested address information referring to the part to be accessed in the processing unit 301 of the processor LSI 121; requester address information for making a reply; and commands etc. Upon receipt of a request, the on-chip interconnect 390 decodes the requested address information and issues a read/write request to the processor LSI 121, and sends it to the control block 385 in the processor LSI 120. The control block 385 outputs a request to the through silicon vias 380, and the control block 385 in the processor LSI 121 receives the request by the through silicon vias 380 in the processor LSI 121. The control block 385 outputs the request to the on-chip interconnect 390 in the processor LSI 121, and the on-chip interconnect 390 in the processor LSI 121 transmits the request to the processing unit 301 in the processor LSI 121 based on the requested address. After having processed the request, the processing unit 301 in the processor LSI 121 returns a reply with the requester address. The information returned is returned to the processing unit 300 in the processor LSI 120 according to the requester address.

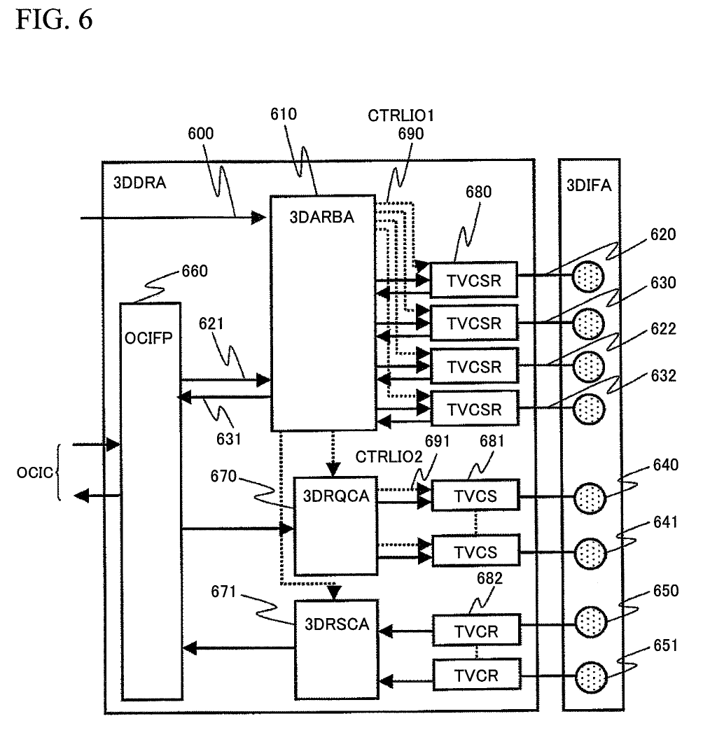

FIG. 6 shows the communication control block 370 to 373 and the through silicon vias 220 to 223 in the processor LSI 120 to 121. The communication control block 370 to 373 arbitrates the right of using the through silicon vias 220 to 223 to be connected. As shown in FIG. 1 and FIG. 5, in order to stack a plurality of processor LSIs manufactured by the identical mask, it is necessary to designate whether or not each communication control block 370 to 373 performs arbitration, and this designation is performed by a designating signal 600 for indicating the communication control block 370 to 373 which has the arbitration function. The designating signal 600 may be of one bit or of multiple bits. One way to impart a value to the designating signal 600 is a method of using a fuse circuit. In the method utilizing a fuse, the fuse is blown by applying a load by electricity or laser etc. during stack assembly so that the designating signal 600 has a desired value. Further, another method of providing the designating signal 600 is a method in which a non-volatile memory device is integrated into the LSI and the output of the non-volatile memory is connected to the designating signal 600 so that the value of the designating signal 600 is written into the non-volatile memory device at the time of stack assembly. Further, another method of providing the designating signal 600 is a method in which the designating signal 600 is drawn out as an LSI external terminal, and a 0/1 signal is connected to the external terminal at the time of stack assembly by using wire bonding etc. Further, another method of providing the designating signal 600 is a method in which the designating signal 600 is connected to the output of a writable storage element from the processing unit 300 to 307, and the designating signal 600 value is written into the storage element by the processing unit 300 to 307 after activation. In this case, it is also possible to arrange that a particular LSI has a special configuration to include the arbitration function without particularly providing the designating signal 600; however, in order for that, the LSI which is to be provided with the arbitration function needs to be manufactured by using a special mask, thereby resulting in an increase in manufacturing cost. In contrast to that, by configuring that the designating signal 600 causes the communication control block 370 to 373 to have the arbitration function as with the present example, the need of particularly configuring the LSI which is provided with the arbitration function is obviated thus enabling to suppress the cost of fabricating masks.

Now, considering the case in which the processor LSI 120 is provided with the arbitration function, the control block 610 receives: a use request signal (signal 620) for through silicon vias 220 to 223 from the processor LSI 121; a use request signal (signal 621) for through silicon vias 220 to 223 from the processing unit 300 to 307 of the own processor LSI (processor LSI 120) and a circuit block such as the DMAC 350 to 351; and a use request signal (signal 622) for through silicon vias 220 to 223 from the external communication LSI 130, to perform the arbitration of the right of using the through silicon vias 220 to 223. To be more specific, the signal 620 is output from the processor LSI 121 and transferred to the control block 610 by the through silicon vias 220 to 223. The signal 621 is output from a circuit block in the processor LSI 120 and transferred to the control block 610 via the internal on-chip interconnect 390 to 391. The signal 622 is output from the external communication LSI 130 and transferred to the control block 610 by the through silicon vias 220 to 223. As the result of arbitration, the control block 610 asserts a use permission signal to a circuit to which the right of use is assigned. The signal 630 is the use permission signal for through silicon vias 220 to 223 to the processor LSI 121; the signal 631 is the use permission signal for through silicon vias 220 to 223 to the processing unit 300 to 307 within the processor LSI 120 and the DMAC 350 to 351; and the signal 632 is the use request signal for through silicon vias 220 to 223 to the external communication LSI 130. The signal 630 is transferred to the processor LSI 121 by the through silicon vias 220 to 223. The signal 631 is transferred to the circuit block which requested the right of use via the internal on-chip interconnects 390 to 391. The signal 632 is output to the external communication LSI by the through silicon vias 220 to 223.

The through silicon via 640 to 641 is a through silicon via for performing access request for memories. The communication control block 370 to 373 of the LSI which has received the use permission for the through silicon vias 220 to 223 outputs a memory access request to the through silicon via 640 to 641. By using the through silicon via 640 to 641, information for synchronizing between the LSIs, LSI selection information for selecting one from a plurality of stacked memory LSIs, command information indicating read/write, address information, processing identifiers, and write data etc. are transmitted to the memory.

The through silicon via 650 to 651 is a through silicon via which the memory returns read-out data etc. The communication control block 370 to 371 which has issued a request receives read-out data, processing identifiers, and signals for performing timing synchronization etc., which are output from the memory.

Further, the interface circuit 660 in FIG. 6 is a connection circuit with the on-chip interconnect 390 to 391; the data conversion circuit 670 is a circuit for converting a read/write request from the on-chip interconnect 390 to 391 into an output format to the through silicon via 640 to 641 and outputting the same at a timing specified in the control block 610; the data conversion circuit 671 is a circuit for selecting necessary data out of the data obtained by the through silicon via 650 to 651 and subjecting the data to format conversion to be output to the interface circuit 660.

The signal control block 680, the signal control block 681, and the signal control block 682 are circuit blocks for performing signal transmission to through silicon vias or signal reception from through silicon vias. The signal control block 680 is a circuit block for two-way transmission/reception and is used for the transmission/reception of use request and use permission signals for the through silicon vias 220 to 223. Further, the control signal 690 and the control signal 691 are signals for controlling the communication with through silicon vias.

Further, the processor LSI to be stacked includes a signal for discriminating LSIs which have the same configuration, such as the processor LSIs. For example, the processing unit 300 to 307 to be mounted in the processor LSI can know, from the information of the signal, how many processing units there are before itself in the processing units 300 to 307. By making this information to be utilized by the program which operates on the processing unit 300 to 307, it is made possible to change operations for each processing unit 300 to 307. This identification signal value is given to each LSI after manufacturing, in the same manner with that for the designating signal 600.

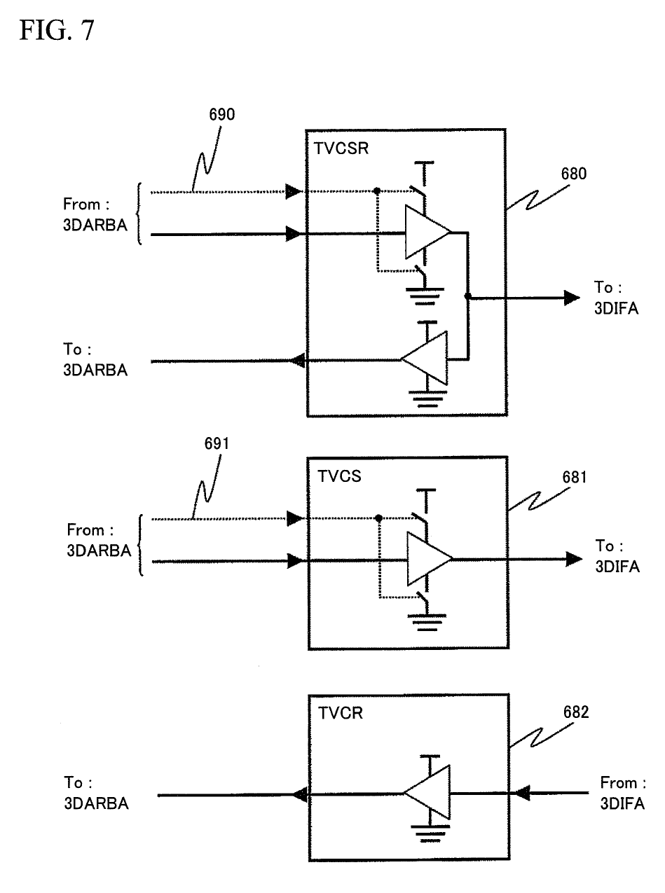

FIG. 7 shows the circuit configuration of the respective circuit block of a signal control block 680, a signal control block 681, and a signal control block 682. The signal control block 681 is a circuit block for outputting signals to through silicon vias. The circuit includes an output terminal to a through silicon via, an input terminal for data to be output, and a control input terminal for designating whether a signal is output or a floating state is kept (or a weak signal is output) regardless of the input signal. In this case, the inputs to the data input terminal and the control input terminal are output by the control block 670 shown in FIG. 6, and the control input terminal of these is connected with the signal 691. This signal 691 is asserted only during the period in which the block, which has obtained the right of using the through silicon vias 220 to 223, outputs data so that the circuit block is activated during that period and data are output from the signal control block 681 to the through silicon vias 220 to 223. During other periods, the signal 691 is floated thereby being deactivated, and the output to the through silicon vias 220 to 223 is put into a high-impedance state regardless of the input value thereby releasing the right of using the through silicon vias 220 to 223 to other circuits. By this configuration, it is made possible to eliminate the effects by the LSI concerned when another LSI performs communication; thereby enabling to perform data communication with a plurality of LSIs by the same through silicon via. This configuration and effect are the same with the signal control block 682 described below.

The signal control block 682 is a circuit for receiving data from a through silicon via.

The signal control block 680 is a circuit to be used for the use request and use permission signals for through silicon vias 220 to 223 in the embodiment of FIG. 6. The signal control block 680 has a circuit configuration which enables both input from a through silicon via and output to a through silicon via. The input and output are switched depending on whether the communication control block 370 to 373 to be connected is responsible for the arbitration function of the through silicon vias 220 to 223. In the present example, description will be made on the case in which arbitration is performed. In this case, a use request for the through silicon vias 220 to 223 from another LSI is received via the signal 620 and the signal 622, and a use permission for the through silicon vias 220 to 223 will be transmitted via the signal 630 and the signal 632. On that account, the signal control block 680 is designated to receive input from the through silicon vias 220 to 223 for the signal 620 and the signal 622; and is designated to perform output to the through silicon vias 220 to 223 for the signal 630 and the signal 632. Further, the signal control block 680 also includes an input/output terminal to a through silicon via, an input terminal from the control block 610 in FIG. 6, and a control input terminal for designating whether a signal is output or a floating state is kept (or a weak signal is output). The input to the control input terminal is connected with the signal 690 output by the control block 610 described in FIG. 6. This signal 690 is asserted only in a period in which the corresponding signal control block 680 performs transmission and has obtained the right of using the through silicon vias 220 to 223 thereby outputting data. That is, a signal is output from the signal control block 680 during the period in which the signal 690 is asserted. Whether the signal control block 680 receives a signal from a through silicon via or transmits a signal to a through silicon via is dependent on the value of the designating signal 600 of FIG. 6.

FIG. 6 and FIG. 7 will have the same configuration in both the processor LSI 120 and the processor LSI 121.

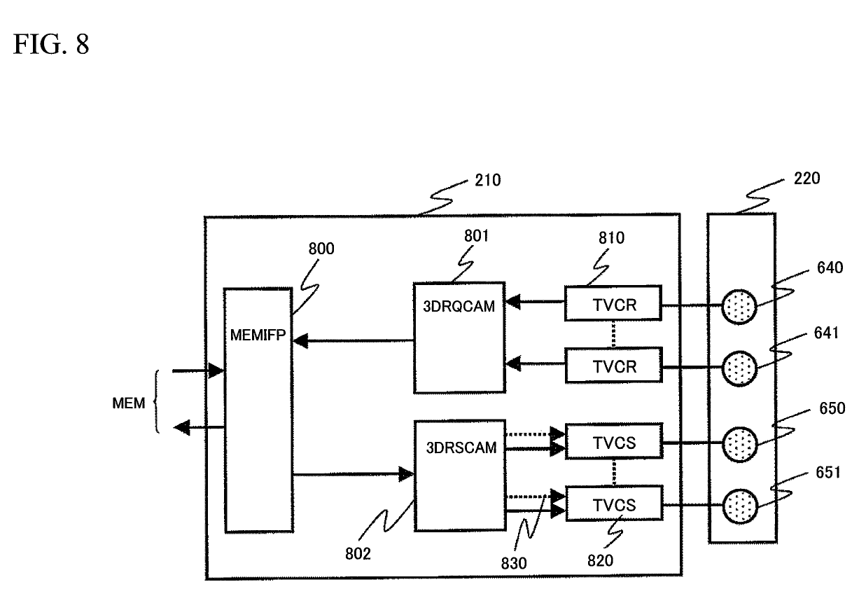

FIG. 8 shows the memory control block 210 to 213 and part of the through silicon vias 220 to 223 in the memory LSI. The interface circuit 800 is a connection circuit with the storage section 200 to 203; the data conversion circuit 801 is a circuit for converting a read/write request from the through silicon vias 220 to 223 into an output format to the storage section 200 to 203 and outputting the same to the storage section 200 to 203; and the data conversion circuit 802 is a circuit for format converting read-out data from the storage section 200 to 203 in conjunction with information associated therewith to output the same to the signal control block 820. A signal control block 810 is connected to the through silicon via 640 to 641, to which a read/write request from and to a memory is connected; and a signal control block 820 is connected to the through silicon via 650 to 651, to which a replay from a memory is returned. The control signal 830 to be connected to the signal control block 820 is asserted only in the period in which data is output to the through silicon vias 220 to 223 and, during this period, the signal control block 681 outputs data to the through silicon vias. In other periods, the signal control block 681 is kept in a floating sate.

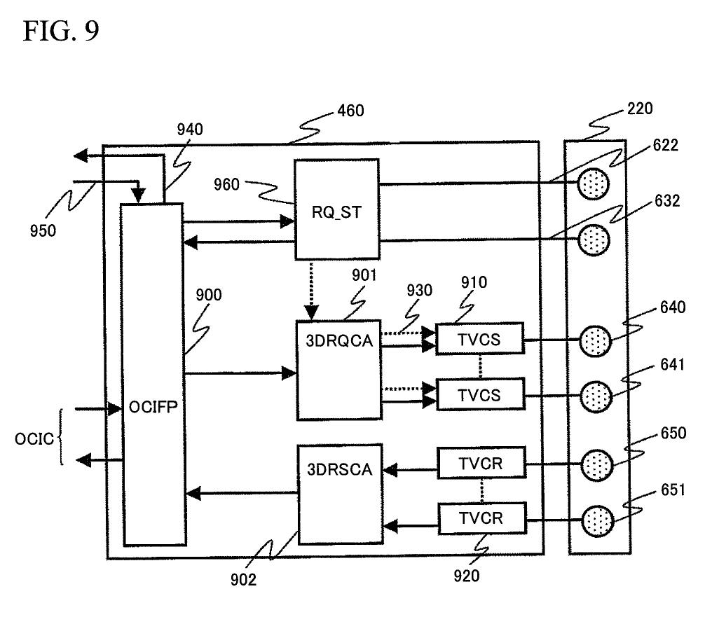

FIG. 9 shows the communication control block 460 to 463 and the through silicon vias 220 to 223 in the external communication LSI 130. The through silicon via 622 to 623 is a through silicon via for performing access request to a memory. The communication control block 460 to 463 of the external communication LSI outputs via the signal 622 a use request for the through silicon via 640 to 641 to the communication control block 370 to 373 of the processor LSI which performs use arbitration of the through silicon vias 640 to 641 and 650 to 651 in the through silicon vias 220 to 223, and acquires a use permission for the through silicon via 640 to 641 via the signal 632. When the permission is obtained, the communication control block 460 to 461 of the external communication LSI performs access request to the memory, which includes information for synchronizing between the LSIs, LSI selection information for selecting one from a plurality of stacked memory LSIs, command information indicating read/write, address information, processing identifiers, and write data etc., by the through silicon via 640 to 641.

The through silicon via 650 to 651 is a through silicon via which the memory returns a reply such as read-out data. The communication control block 460 to 464 of the external communication LSI receives information output from the memory, such as read-out data, processing identifiers, and signals for performing timing synchronization between LSIs, by the through silicon via 650 to 651.

Further, the interface circuit 900 in FIG. 9 is a connection circuit with the on-chip interconnect 450 to 451; the data conversion circuit 901 is a circuit for converting a read/write request from the on-chip interconnect 450 to 451 into an output format to the through silicon via 640 to 641 and outputting the same at the timing specified by the control block 960; and the data conversion circuit 902 is a circuit for selecting necessary data out of the data obtained by the through silicon via 650 to 651 and format converting and outputting the same to the interface circuit 900.

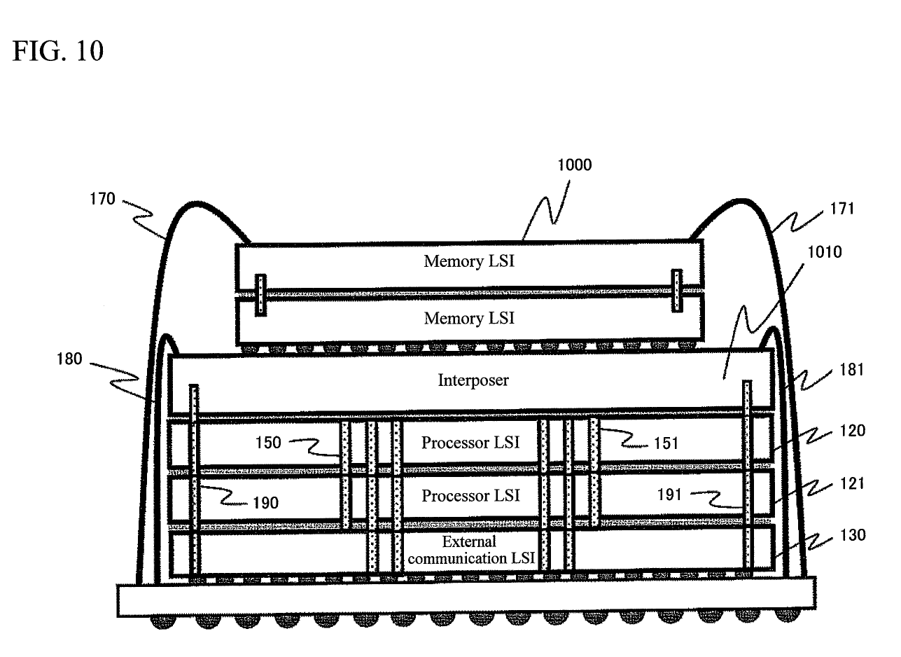

FIG. 10 shows an example of the case in which stacking is performed without forming a through silicon via in the memory LSI to be stacked in the uppermost layer. As shown in the figure, if the memory LSI 1000 is purchased from outside, a metal terminal such as a ball is prepared as the input/output terminal. In order to stack and connect this memory LSI with the external LSI and the processor LSI, an interposer 1010 is inserted. This makes it possible to connect the wirings of the memory LSI and the processor LSI which have different sizes and positions of input/output terminals, thus increasing the degree of flexibility for arranging the memory LSI to be stacked. Further, using a material and structure having an excellent heat dissipating property for the interposer 1010 enables to improve the heat dissipating property of the memory LSI and achieve a significant effect in reducing power consumption when the stacked LSI is used for applications in which the data retention time in the memory LSI in the package is long. Further, it is without saying that placing a radiator plate on top of the memory LSI in the uppermost layer will improve heat dissipating property thereby achieving similar effects as described above.

Seeing from a different aspect, the present example can be considered as an example to ensure the degree of flexibility for the arrangement above the interposer by proving an interposer above the external communication LSI and the processor LSI. Especially, an arrangement that a memory LSI is placed above the interposer layer is preferable in the viewpoint of the degree of flexibility in design. This arrangement is effective, above all, in the cases of a DRAM, and a phase-change memory, etc., which are susceptible to heat effect.

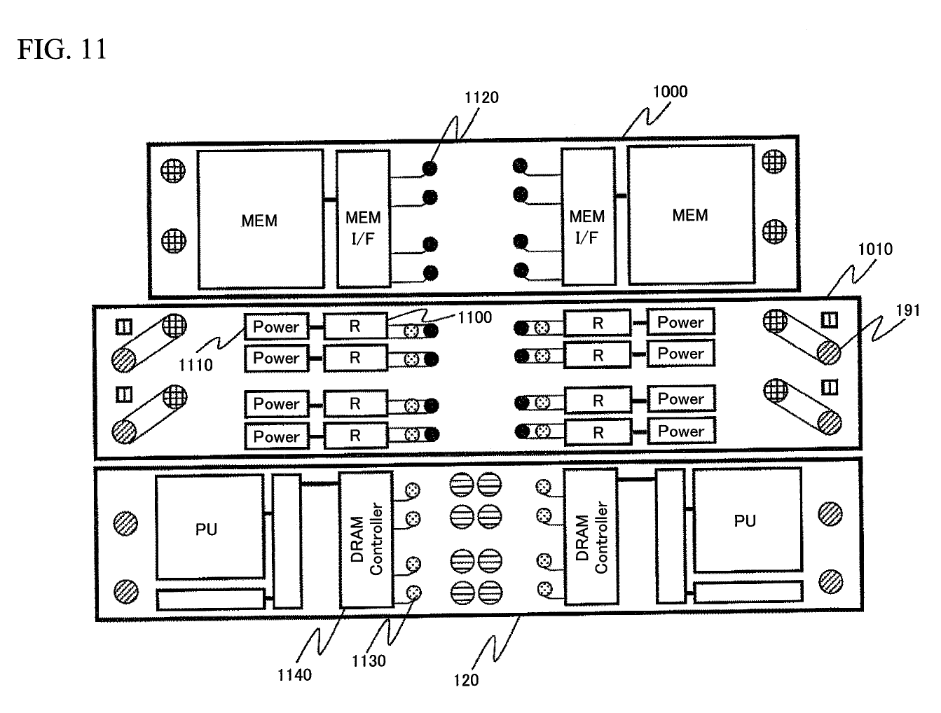

FIG. 11 shows an example of the interposer 1010. The interposer 1010 is stacked between the memory LSI 1000 and the processor LSI 120, and is provided for connecting between the memory LSI 1000 and the processor LSI 120 with wiring. Further, seeing from a different aspect, the interposer is provided in order to dispose connection terminals on the upper face thereof for connecting the memory LSI 1000. In this example, description will be made on the case in which a generally standardized DRAM is stacked as the memory LSI. When access to the memory LSI is performed from the DRAM controller 1140 mounted on the processor LSI 120 or the external communication LSI, the connection is made taking into consideration the resistance and reflection on the substrate in the case of a two dimensional wiring. However, in the case in which stacking is performed, physical parameters including the distance between the DRAM controller and the memory LSI are significantly different. Accordingly, a configuration in which the through silicon vias 1120 and 1130, wiring resistor 1100, and power supply 1110 in the interposer 1010 are made up of circuits and necessary physical parameters is formed by those circuits, will enable the connection with a standardized memory LSI. The interposer may be manufactured by a semiconductor process of a large gate width transistor, which is more advantageous in cost than using a finer semiconductor process. Moreover, the interposer needs not be manufactured by a semiconductor process, but may be made up of a package board, and a system board etc. Further, the interposer may be made up of an FPGA etc. which allows to change the wiring structure after manufacture. Configuring some of the wiring parameters to be changeable will enable to improve the degree of flexibility for arranging the memory LSI to be stacked on the top face.

Further, this interposer may also be configured to only perform the connection of wiring and heat dissipation, and can be provided for realizing both the function of connecting between the above described memory LSI 1000 and the processor LSI 120 with wiring and the function of heat dissipation. Above all, when the area of the memory LSI 1000 is smaller than that of the processor LSI 120 as shown in FIG. 10, it becomes possible to dissipate heat from the top face of the interposer thereby enabling more efficient heat dissipation from the processor LSI 120.

This interposer enables to manufacture a stacked package without forming through silicon vias in the memory LSI, thus enabling the reduction of the development cost.

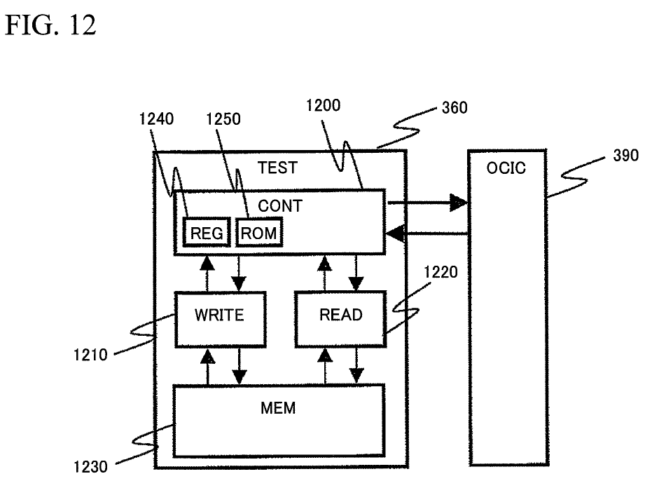

FIG. 12 shows the test blocks 360 to 361 and 430 to 431. The test blocks are mounted in the processor LSI and the external communication LSI, and are used to perform an operational test of the processor LSI and the external communication LSI before stacking the memory LSI. As shown in the figure, the test block 360 is connected to the on-chip interconnect 390 and performs the communication with other stacked LSIs to transmit and receive data. The control section 1200 transmits addresses and data to the write section 1210; and the write section 1210 stores data in the storage section 1230. Further, the control section 1200 transmits addresses and control signals to the read section 1220, and the read section reads data from the storage section 1230 and transmits the same to the control section. Further, the control section has a function to evaluate the correspondence between the received data obtained through the on-chip interconnect and the data stored in the storage section 1230, and thereby is able to perform the test of communication control. More specifically, the test of communication performance may be performed by providing a circuit for measuring a delay etc. in the communication with other LSIs, in the present test block or in the through silicon via control block shown in FIG. 6. This test may be performed by using a test program stored in the ROM 1250 in the control section 1200, or may be performed by a register 1240 which is controlled by a microcontroller 420 via the on-chip interconnect 390. Further, the transmission data and expected values of the communication test may be stored in the ROM 1250 in the control section 1200.

This makes it easy to perform the stacking test of the processor LSI and the external communication LSI in the step prior to stacking the memory LSI.

Seeing from the aspect of the method of manufacturing semiconductor devices, the invention described in FIGS. 10 to 12 may be considered as a method of manufacturing semiconductor devices, comprising the steps of: stacking an external communication LSI above a package board; after stacking the external communication LSI, stacking a processor LSI above the external communication LSI; after stacking the processor LSI, stacking an interposer layer; and providing a through silicon via.

The process steps described above are performed by the same vendor. In this respect, provided with an interposer layer, the step of stacking a memory LSI above the interposer layer can be performed by a different vendor, which will be a suitable manufacturing method especially when the memory LSI is supplied by a separate vendor. Further, even when the same vendor performs the process steps through the stacking of the memory LSI, the need of providing through silicon vias passing through the memory LSI is obviated, which will bring effects of increasing the yield and reducing the development cost.

Furthermore, when manufacturing is performed by the above described process steps, since an operational test between the external communication LSI and the processor LSI can be performed before stacking the memory LSI, manufacturing at a reduced risk upon failure of stacking becomes possible.

What is claimed is:

1. A semiconductor device, comprising:
a package board;
a first LSI connected to the package board and including a communication circuit performing communication through the package board;
a second LSI provided above the first LSI and performing arithmetic processing;
a third LSI provided above the second LSI and including a first storage device storing a result of arithmetic processing of the second LSI, the first storage device including a plurality of first memory cells provided at intersection points of a plurality of first bit lines and a plurality of first word lines; and
a first through silicon via provided so as to pass through the second LSI and electrically connecting the first, second, and third LSIs with one another.

2. The semiconductor device according to claim 1, further comprising:
an interposer layer provided between the second LSI and the third LSI and connecting between the second LSI and the third LSI with wiring.

3. The semiconductor device according to claim 2, wherein
the third LSI is configured such that its surface on which circuitry is disposed has a first area different from a second area of a surface of the second LSI on which circuitry is disposed.

4. The semiconductor device according to claim 2, wherein
the third LSI is configured such that the position of its connection terminal is different from that of a connection terminal of the second LSI.

5. The semiconductor according to claim 1, wherein
the first LSI includes a first test circuit;
the second LSI includes a second test circuit; and
the first test circuit and the second test circuit are adapted to perform a communication test between the first LSI and the second LSI through the first through silicon via.

6. The semiconductor device according to claim 1, wherein
the plurality of first memory cells are DRAM cells.

7. The semiconductor device according to claim 1, wherein
a first power supply is provided to the first LSI, the second LSI, and the third LSI through the first through silicon via.

8. The semiconductor device according to claim 1, further comprising:
a first bonding wire connecting the package board with the second LSI; and
a second bonding wire connecting the package board with the third LSI, wherein
a second power supply is provided to the second LSI through the first bonding wire, and
a third power supply is provided to the third LSI through the second bonding wire.

9. The semiconductor device according to claim 1, wherein
the second LSI receives communication data from the first LSI through the first through silicon via, and
the second LSI stores processed data resulting from arithmetic processing of the communication data, into the plurality of first memory cells through the first through silicon via.

10. The semiconductor device according to claim 1, further comprising:
a fourth LSI provided between the first LSI and the second LSI, and performing arithmetic processing and storing a result of the arithmetic processing into the first storage device, wherein
when the second LSI requests the third LSI of the transmission/reception of first data, the second LSI causes a first request signal corresponding to the transmission/reception of the first data to include a first identifier indicating that the source of the first request signal is the second LSI, and
when the fourth LSI requests the third LSI of the transmission/reception of second data, the fourth LSI causes a second request signal corresponding to the transmission/reception of the second data to include a second identifier for indicating that the source of a second request signal is the fourth LSI.

11. The semiconductor device according to claim 1, further comprising:
a fifth LSI provided above the third LSI and including a second storage device storing the result of arithmetic processing of the second LSI; the second storage device including a plurality of second memory cells provided at intersection points of a plurality of second bit lines and a plurality of second word lines, wherein
when the second LSI requests the third LSI of the transmission/reception of third data, the second LSI causes a third request signal corresponding to the transmission/reception of the third data to include a third identifier for indicating that the destination of the third request signal is the third LSI, and
when the second LSI request the fifth LSI of the transmission/reception of fourth data, the second LSI causes a fourth request signal corresponding to the transmission/reception of the fourth data to include a fourth identifier for indicating that the destination of the fourth request signal is the fifth LSI.

12. A semiconductor device, comprising:
a package board;
a first LSI connected to the package board and including a communication circuit performing communication via the package board;
a second LSI provided above the first LSI and performing arithmetic processing using data from the communication circuit;
a first through silicon via configured to pass through the second LSI and for electrically connecting the first and second LSIs; and
an interposer layer provided above the second LSI, electrically connected to the first through silicon via, and provided on its top with a connection terminal for connecting another circuit.

13. The semiconductor device according to claim 12, wherein
the first LSI includes a first communication section performing communication with an LSI outside the first LSI;
the second LSI includes a second communication section performing communication with an LSI outside the second LSI; and
the interposer layer connects the first communication section or the second communication section with an LSI other than the first LSI and other than the second LSI.

14. The semiconductor device according to claim 12, further comprising
a third LSI including a first storage device storing result of arithmetic processing of the second LSI, the first storage device including a plurality of first memory cells at intersection points of a plurality of first bit lines and a plurality of first word lines, wherein
the interposer layer is adapted to electrically connect the first LSI and the second LSI with the third LSI.

15. The semiconductor device according to claim 12, wherein
the first LSI includes a first test circuit;
the second LSI includes a second test circuit; and
the first test circuit and the second test circuit are adapted to perform a communication test between the first LSI and the second LSI through the first through silicon via.

16. The semiconductor device according to claim 12, wherein
the plurality of first memory cells are DRAM cells.

17. A method of manufacturing a semiconductor device in which a plurality of LSIs are stacked, the method comprising:
a first step of stacking a first LSI above a package board, the first LSI including a communication circuit for performing communication via the package board;
after the first step, a second step of stacking a second LSI above the first LSI, the second LSI being adapted to perform arithmetic processing using data from the communication circuit;
after the second step, a third step of providing an interposer layer above the second LSI, the interposer layer being adapted to connect between the first LSI or the second LSI and an LSI other than the first LSI and other than the second LSI with wiring; and
after the third step, a fourth step of providing a first through silicon via configured to pass through the second LSI and adapted to electrically connect the first LSI and the second LSI with each other.

18. The method of manufacturing a semiconductor device according to claim 17, further comprising:
after the fourth step, a fifth step of testing communication between the first LSI and the second LSI via the first through silicon via.

19. The method of manufacturing a semiconductor device according to claim 17, further comprising
after the fourth step, a sixth step of providing a third LSI including a first storage device for storing a result of arithmetic processing of the second LSI, the first storage device being connected with the first LSI or the second LSI by the interposer layer and having a plurality of first memory cells provided at intersection points of a plurality of first bit liens and a plurality of first word lines.
